(19) United States
(12) Patent Application Publication
(10) Pub. No.: US 2002/0104990 A1
(43) Pub. Date: Aug. 8, 2002

(54) Across-wafer optical MEMS device and protective lid having across-wafer light-transmissive portions

(76) Inventors: Dana Richard DeReus, Colorado Springs, CO (US); Shawn Jay Cunningham, Colorado Springs, CO (US); Arthur S. Morris, Raleigh, NC (US)

Correspondence Address: JENKINS & WILSON, PA, 3100 TOWER BLVD, SUITE 1400, DURHAM, NC, 27707, US

(21) Appl. No.: 10/025,978

(22) Filed: Dec. 19, 2001

Related U.S. Application Data
(60) Provisional application No. 60/256,674, filed on Dec. 20, 2000.
(60) Provisional application No. 60/256,604, filed on Dec. 19, 2000.
(60) Provisional application No. 60/256,607, filed on Dec. 19, 2000.
(60) Provisional application No. 60/256,610, filed on Dec. 19, 2000.
(60) Provisional application No. 60/256,611, filed on Dec. 19, 2000.
(60) Provisional application No. 60/256,683, filed on Dec. 19, 2000.
(60) Provisional application No. 60/256,688, filed on Dec. 19, 2000.
(60) Provisional application No. 60/256,689, filed on Dec. 19, 2000.
(60) Provisional application No. 60/260,558, filed on Jan. 9, 2001.

(51) Int. Cl. H01L 29/06

(52) U.S. Cl. 257/20

(57) ABSTRACT

An across-wafer optical MEMS device includes a protective lid having across-wafer light-transmissive portions. The across-wafer optical MEMS device allows light to pass in a direction substantially parallel to a surface on which the optical MEMS device is mounted. The light-transmissive portions in the protective lid allow light to pass from an optical device located on one side of the optical MEMS device to a second device located on another side of the optical MEMS device. A plurality of optical MEMS devices can be located on the substrate and enclosed by the same lid without wafer-level encapsulation of each optical MEMS device.

### RELATED APPLICATIONS

This application claims the benefit of U.S. provisional patent application No. 60/256,674 filed Dec. 20, 2000, U.S. provisional patent application No. 60/256,604 filed Dec. 19, 2000, U.S. provisional patent application No. 60/256,607 filed Dec. 19, 2000, U.S. provisional patent application No. 60/256,610 filed Dec. 19, 2000, U.S. provisional patent application No. 60/256,611 filed Dec. 19, 2000, U.S. provisional patent application No. 60/256,683 filed Dec. 19, 2000, U.S. provisional patent application No. 60/256,688 filed Dec. 19, 2000, U.S. provisional patent application No. 60/256,689 filed Dec. 19, 2000, and U.S. provisional patent application No. 60/260,558 filed Jan. 9, 2001, the disclosures of which are incorporated herein by reference in their entirety.

### TECHNICAL FIELD

The present invention relates to optical MEMS devices. More particularly, the present invention relates to an across-wafer optical MEMS device and a protective lid having across-wafer light-transmissive portions.

### BACKGROUND ART

MEMS are small-scale devices, (e.g., devices ranging from about 1 micrometer in size to about 1 millimeter in size) that have functionality in physical domains further than integrated circuits. For example, MEMS devices may perform solid mechanics, fluidics, optics, acoustics, magnetics, and other functions. The term MEMS, as used herein, also refers to devices and systems constructed using microfabrication technologies commonly used to make integrated circuits.

Because of the small size of optical MEMS devices, protecting optical MEMS devices from contamination, such as particle contamination, during manufacturing and operation is essential. For example, a single dust particle can prevent an optical MEMS device, such as a shutter, from operating properly. In order to provide protection for optical MEMS devices, optical MEMS devices have conventionally been encapsulated using a package with a single opening or light-transmissive portion for optical communication with external devices. Such packages do not allow across-wafer optical communication. Light comes in through the opening, interacts with the optical MEMS device, and exits through the same opening.

Providing a single aperture in an optical MEMS device package also imposes constraints on alignment of external devices with the optical MEMS device. Other optical MEMS devices include complex waveguides for guiding light to and from the optical MEMS device. Such waveguides are expensive and difficult to fabricate.

Accordingly, in all in light of the difficulties associated with conventional optical MEMS devices, there exists a long-felt need for an improved optical MEMS device and a protective lid for the optical MEMS device.

### DISCLOSURE OF THE INVENTION

According to one aspect of the invention, an across-wafer optical mircoelectromechanical system includes a substrate having a first surface. An optical MEMS device is located on the first surface for altering the flow of light in a direction parallel to the first surface. A protective lid covers the optical MEMS device. The lid includes first and second light-transmissive portions for providing an optical path from a first optical device or devices located on a first edge of the substrate to a second optical device or devices located on a second edge of the substrate in a direction parallel to the surface.

Accordingly, it is an object of the invention to provide an across-wafer optical MEMS device and a protective lid having across-wafer light-transmissive portions.

An object of the invention having been stated hereinabove and which is achieved in whole or in part by the present invention, other objects will become evident as the description proceeds when taken in connection with the accompanying drawings as best described hereinbelow.

### BRIEF DESCRIPTION OF THE DRAWINGS

Preferred embodiments of the invention will now be explained with reference to the accompanying drawings of which:

FIG. 1 is a sectional view of an across-wafer optical MEMS device mounted on a substrate suitable for use with embodiments of the present invention;

FIG. 2A is a sectional end view and FIG. 2B is a sectional side view through line B-B in FIG. 2A of an across-wafer optical MEMS device according to an embodiment of the present invention;

FIG. 2C is a sectional end view and FIG. 2D is a sectional side view through line D-D in FIG. 2C of an across-wafer optical MEMS device according to another embodiment of the present invention;

FIG. 2E is a sectional end view and FIG. 2F is a sectional side view through line F-F in FIG. 2E of an across-wafer optical MEMS device according to another embodiment of the present invention;

FIG. 3 is a sectional view of an optical MEMS device including anti-reflective coatings according to an embodiment of the present invention;

FIG. 4A is a top view and FIG. 4B is a sectional view through line B-B in FIG. 4A of a curling across-wafer optical MEMS device according to an embodiment of the present invention;

FIG. 4C is a top view and FIG. 4D is a sectional view through line D-D illustrated in FIG. 4C of a sliding across-wafer optical MEMS device according to an embodiment of the present invention;

FIG. 4E is a top view and FIG. 4F is a sectional view through line F-F illustrated in FIG. 4E of a torsional beam across-wafer optical MEMS device according to an embodiment of the present invention;

FIG. 4G is a top view and FIG. 4H is a sectional view through line H-H illustrated in FIG. 4G of a pop-up across-wafer optical MEMS device according to an embodiment of the present invention;

FIG. 4I is a top view and FIG. 4J is a sectional view through line J-J illustrated in FIG. 4I of a cantilevered shutter across-wafer optical MEMS device according to an embodiment of the present invention;

FIG. 5A a top view and FIG. 5B is a sectional view through line B-B illustrated in FIG. 5A of a torsional beam across-wafer optical MEMS device according to an embodiment of the present invention;

FIG. 6A is a top view and FIG. 6B is an end view of a cantilever beam across-wafer optical MEMS device according to an embodiment of the present invention;

FIG. 7 is a top view of a torsional pivot across-wafer optical MEMS device according to an embodiment of the present invention; and

FIG. 8A is a top view and FIG. 8B is an end view of a piezoelectric cantilever optical MEMS device according to an embodiment of the present invention.

### DETAILED DESCRIPTION OF THE INVENTION

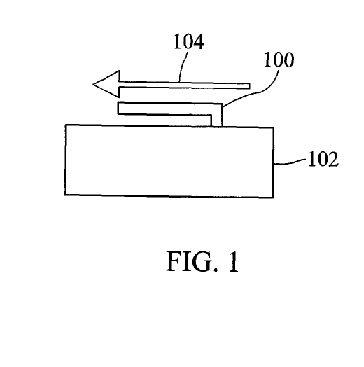

FIG. 1 illustrates an across-die/wafer optical MEMS device suitable for use with embodiments of the present invention. In FIG. 1, a generic optical MEMS device 100 is shown. Optical MEMS device 100 is mounted on a substrate 102. An arrow 104 illustrates an exemplary path for light across substrate or wafer 102. In operation, optical device 100 can move to affect, e.g., interrupt, reflect, redirect, filter, or otherwise interact with, light traveling through the optical path indicated by arrow 104.

In order to protect an across-wafer optical MEMS device in manufacturing and operating environments, it is desirable to enclose or cover the optical MEMS device. One method for covering an across-wafer optical MEMS device, such as device 100 illustrated in FIG. 1, is to place a protective lid over the optical MEMS device. A separate cover or lid may be placed over each optical MEMS device. Alternatively, a single lid may be placed over multiple optical MEMS devices. Either embodiment is intended to be within the scope of the invention.

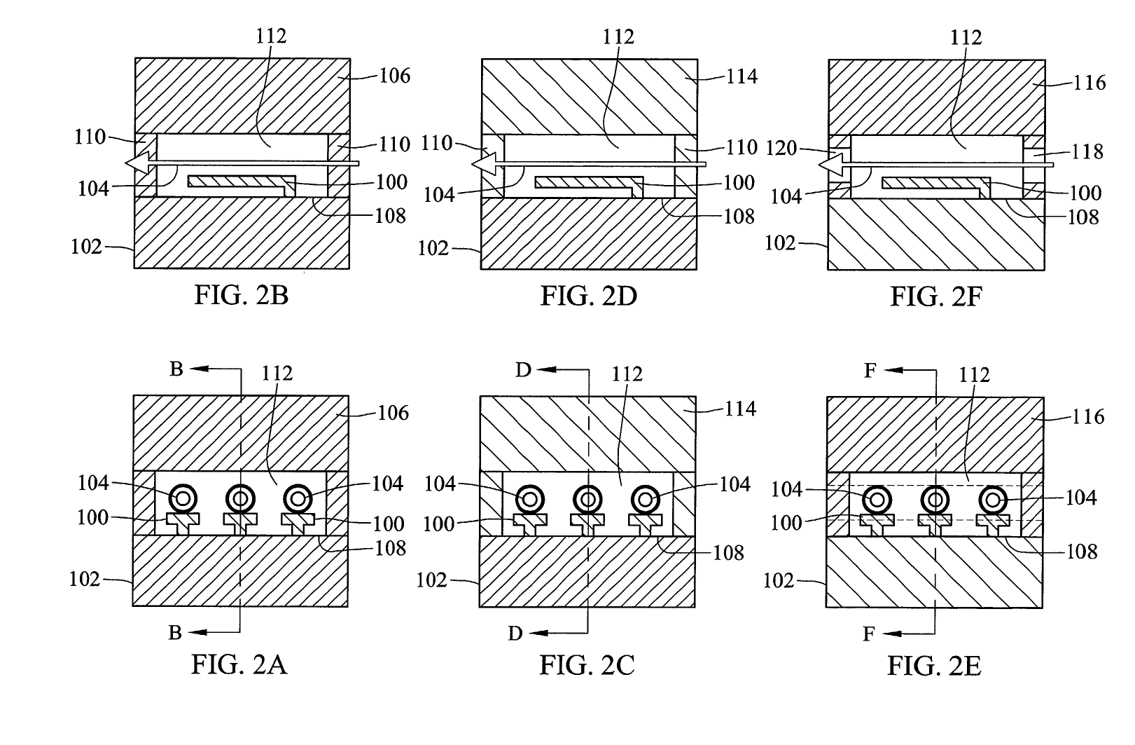

FIG. 2A is a sectional end view and FIG. 2B is a sectional side view of an across-wafer optical MEMS device including a protective lid according to an embodiment of the present invention. In FIG. 2A, a plurality of optical MEMS devices 100 are mounted on a substrate 102. Light travels in a direction out of the page across optical MEMS devices 100 as indicated by arrows 104 in FIG. 2A and in a direction across the page over optical MEMS devices 100 in FIG. 2B.

In order to protect optical MEMS devices, provide a hermetic environment, and also to provide a path across substrate 102 for light, a protective lid 106 can be bonded to substrate 102. In the embodiment illustrated in FIGS. 2A and 2B, protective lid 106 is assumed to be made of the same material as substrate 102. Exemplary materials suitable for forming lid 106 and substrate 102 include silicon, glass, or gallium arsenide. Protective lid 106 can be bonded to substrate 102 using any suitable bonding method, such as anodic bonding, fusion bonding, Au eutectic bonding, glass frit bonding, epoxy bonding, or other bonding methods. In order to allow passage of light in a direction parallel to surface 108 of substrate 102, lid 106 includes light-transmissive portions 110. Light-transmissive portions 110 can be apertures or made of a light-transmissive material or a combination of both. The particular material used depends on the frequency of light desired to be passed. For example, if it is desired to pass light in the visible range, light-transmissive portions 110 can be made of glass. Alternatively, if it is desired to pass light in the infrared range, light-transmissive portions may be made of silicon.

The present invention is not limited to forming light-transmissive portions 110 as part of lid 106. In an alternative embodiment, light-transmissive portions 110 can be formed as part of substrate 102, for example, by etching a cavity in substrate 102. In yet another alternative embodiment, light-transmissive portions can be part of both lid 106 and substrate 102. That is, recess 112 in which optical MEMS device 100 is enclosed can be formed by recesses in both lid 106 and substrate 102. Any suitable method for manufacturing a substrate and a lid for an optical MEMS device that allows light to pass in a direction parallel to the surface on which the optical MEMS device is mounted is intended to be within the scope of the invention. Light-transmissive portions 110 can be coated with an anti-reflective coating to reduce internal and external reflections. Exemplary anti-reflective coatings suitable for use with embodiments of the present invention will be discussed in detail below.

FIGS. 2C and 2D illustrate an across-wafer optical MEMS device having a protective lid according to an alternate embodiment of the present invention. More particularly, FIG. 2C is a sectional end view of an across-wafer optical MEMS device, and FIG. 2D is a sectional side view of an across-wafer optical MEMS device through line D-D illustrated in FIG. 2C. In FIGS. 2C and 2D, optical MEMS device 100 is mounted on substrate 102 as in FIGS. 2A and 2B. However, in FIGS. 2C and 2D, protective lid 114 is made of a different material than substrate 102. For example, substrate 102 can be made of silicon and lid 114 can be made of glass. The remaining elements of the embodiment illustrated in FIGS. 2C and 2D are the same as the correspondingly numbered elements illustrated in FIGS. 2A and 2B. Hence, a description thereof will not be repeated herein.

FIGS. 2E and 2F illustrate yet another embodiment of an across-wafer optical MEMS device having a protective lid according to the present invention. More particularly, FIG. 2E is a sectional end view of an across-wafer optical MEMS device and FIG. 2F is a sectional side view of the across-wafer optical MEMS device illustrated in FIG. 2E taken through line F-F in FIG. 2E. In FIG. 2E, a plurality of optical MEMS devices are mounted on a substrate 102. A protective lid 116 is bonded to substrate 102 to protect optical MEMS devices 100. In order to allow transmission of light in a direction parallel to surface 108 of substrate 102, lid 116 includes first and second apertures 118 and 120 located on opposite sides of MEMS device 100. The remaining elements of the embodiments illustrated in FIGS. 2D and 2E are the same as the correspondingly numbered elements previously described. Hence, a description thereof will not be repeated herein.

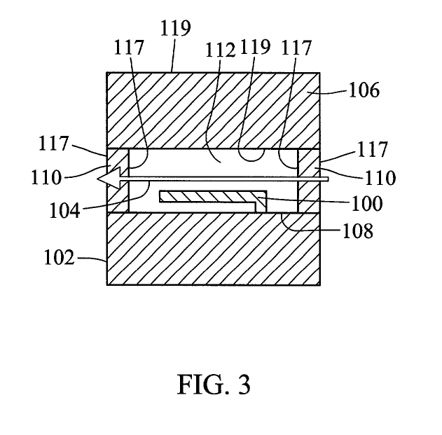

As stated above, an across-wafer optical MEMS device according to an embodiment of the present invention can include anti-reflective coatings on surfaces in the optical path. FIG. 3 is a sectional view of an optical MEMS device having a protective lid according to embodiment of the present invention similar to the embodiment illustrated in FIG. 2B. In FIG. 3, exemplary surfaces on which anti-reflective coatings can be located are illustrated in detail. More particularly, in FIG. 3, all internal and external surfaces of lid 106 within the optical path are preferably coated with an anti-reflective coating. For example, in the illustrated embodiment, surfaces 117 of light-transmissive portions 110 and surfaces 119 of lid 116 can be coated with an anti-reflective coating. The particular anti-reflective coating depends on the wavelength of light to be transmitted. In one example, the anti-reflective coating may be a single layer anti-reflective coating having a thickness is given by n_{f}d_{f}=λ/4, where n_{f} is the film index of a fraction, d_{f} is the film thickness, and λ is the wavelength of the incident light. The ideal index of refraction of the film may be given by n_{f}=\sqrt{n₁n₂}, where n_{f}, n₁, and n₂ are the indices of refraction for the anti-reflective film and the bounding media, respectively. For single layer film on silicon, experiments have shown that low losses occur through a 190 nm Si₃N₄ film at a center wavelength of approximately 1574 nm. If lid 106 is made of glass, magnesium fluoride (MgF₂) and Cryolite™ are possible candidates for anti-reflective coatings. In a second example, the anti-reflective coating can have multiple layers.

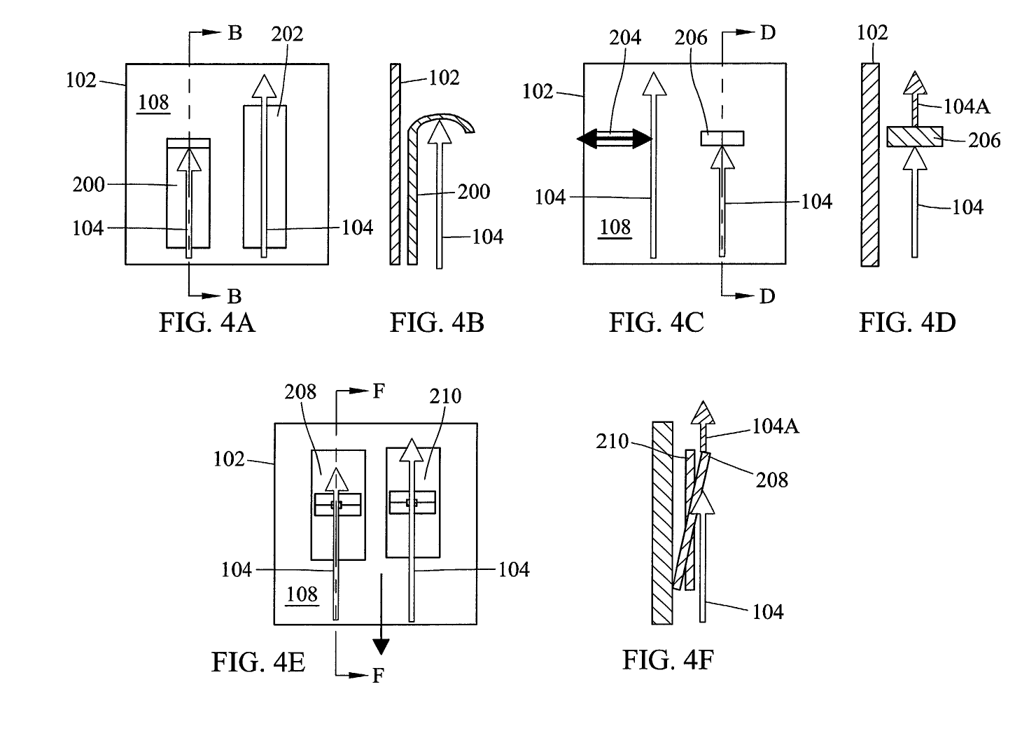

In the embodiments described above, optical MEMS device 100 has been described generically as a device that affects light as it travels the optical path across substrate 102. FIGS. 4A-8B illustrate exemplary across-wafer optical MEMS devices suitable for use with embodiments of the present invention. Referring to FIGS. 4A and 4B, an optical MEMS device that curls out of plane to affect the flow of light across substrate 102 is illustrated. More particularly, FIG. 4A is a top view of substrate 102 and optical MEMS devices 200 and 202, each comprising an elongate member that curls out of plane. By “out of plane,” it is meant that the optical MEMS device curls in a direction orthogonal to the plane containing surface 108 of substrate 102 in its unactuated state. In FIG. 4A, curling optical MEMS device 200 is shown in its actuated state to block the flow of light across surface 108 of substrate 102, and curling optical MEMS device 202 is shown in its unactuated state to allow light to pass across the surface 108 of substrate 102.

FIG. 4B is a sectional side view illustrating the curling of optical MEMS device 200 to affect the flow of light across substrate 102. Optical MEMS devices 200 and 202 that curl out of plane can be implemented with electrostatic, thermal, magnetic, or piezoelectric components. For example, parallel plate electrostatic actuation can be used to pull an initially curled cantilever down to a substrate. The initial curl in the cantilever can be accomplished by using residual film stresses present in a bimetallic cantilever or by plastically deforming the cantilever through thermal heating. In a similar manner, an initially curled bimetallic cantilever beam can be driven down to a substrate by Joule heating of the bi-materials. Because one material thermally expands and contracts at a different rate than the other material, a curl can be achieved. A cantilever beam can also be made to lay flat or curl out of plane by inducing Joule heating in a beam with a shape memory alloy material. In an alternative actuation method, magnetic actuation can be used to pull an initially curled cantilever beam towards or away from the substrate through the interaction of an electromagnetic coil or magnetic material on the beam and then external magnetic field. Piezoelectric actuation can be used to control the curvature of the cantilever beam by using the expansion of a piezoelectric material in a bimetallic system. For example, one of the materials that form optical MEMS devices 200 and 202 can be a piezoelectric material. Since a mechanical strain can be induced in a piezoelectric material through application of an electric field, applying a charge to such a material can be used to achieve a curling effect.

FIGS. 4C and 4D illustrate another optical MEMS device suitable for affecting the flow of light across substrate 102 according to an embodiment of the present invention. In FIGS. 4C and 4D, members 204 and 206 are slidingly mounted on substrate 102 and extend in a direction orthogonal to the path of light across substrate 102. Members 204 and 206 can block or alter the wavelength content, e.g., by filtering or passing predetermined wavelengths, of light as it passes across surface 108 of substrate 102. For example, members 204 and 206 can be made of a non-light-transmissive material to block the flow of light across surface 108 of substrate 102. In an alternate embodiment, as illustrated in FIG. 4D, member 206 comprises a filter that alters the wavelength content of incident light indicated by arrow 104 such that the transmitted light indicated by arrow 104A has a different wavelength content than the incident light. Members 204 and 206 move across substrate 102 in a direction perpendicular to the light flow path to selectively affect the flow of light. Motion in the same plane as surface 108 of substrate 102 is commonly referred to as in-plane motion. In the embodiment illustrated in FIG. 4C, member 204 is not in the optical path, and member 206 is located in the optical path to affect the flow of light. Movement of members 204 and 206 can be achieved through any suitable means, such as electrostatic, thermal, or magnetic force.

FIGS. 4E and 4F illustrate yet another type of optical MEMS device suitable for affecting the flow of light across the surface of substrate 102 according to an embodiment of the present invention. In FIG. 4E and 4F, optical MEMS devices 208 and 210 comprise torsionally-suspended shutters that can be actuated through the use of variable gap electrostatic coupling between the shutters and a fixed electrode. More particularly, as illustrated in FIG. 4F, optical MEMS device 208 can be torsionally suspended above an electrode (not shown). In operation, a charge can be applied to the electrode to achieve out of plane motion of optical MEMS devices 208 and 210 and selectively affect the flow of light across surface 108 of substrate 102. As with the embodiment illustrated in FIGS. 4C and 4D, optical MEMS devices 208 and 210 can block, reflect, or change the wavelength content of incident light.

FIGS. 4G and 4H illustrate yet another type of optical MEMS device suitable for affecting the flow of light across substrate 102 according to an embodiment of the present invention. In FIG. 4G, optical MEMS devices 212 and 214 comprise pop-up shutters that move from an in-plane position to an out-of-plane position to affect the optical path. More particularly, as illustrated in FIG. 4H, optical MEMS device 212 moves from a position parallel to surface 108 of substrate 102 to a direction perpendicular to surface 108 of substrate 102. Such motion may be achieved through electrostatic, magnetic, or thermal forces. Optical MEMS devices 212 and 214 can block, reflect, or alter the wavelength content of incident light depending on the desired application.

FIGS. 4I and 4J illustrate yet another embodiment of an optical MEMS device suitable for affecting the optical path across substrate 102 according to an embodiment of the present invention. In FIG. 4I, optical MEMS devices 216 and 218 comprise cantilevered shutters that achieve out-of-plane motion to affect the optical path. More particularly, as illustrated in FIG. 4J, shutter 216 moves in a direction perpendicular to the plane of surface 108 of substrate 102 to affect the flow of light. Such out of plane motion can be achieved through the use of an electrostatic variable gap capacitor, a thermal or piezoelectric bimorphic material, or an electromagnetic coil and an electromagnetic field.

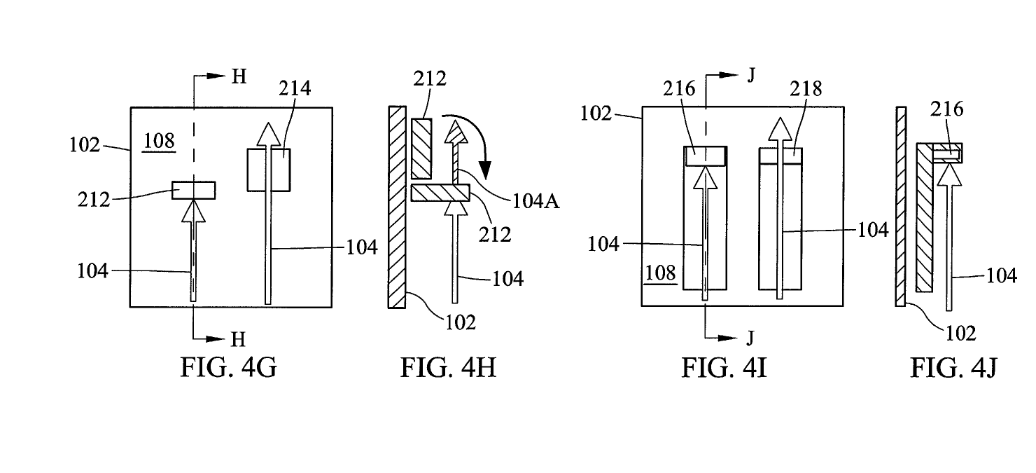

FIGS. 5A and 5B illustrate optical MEMS device 208 illustrated in FIGS. 4E and 4F in more detail. In FIG. 5A, optical MEMS device generally designated 208 comprises an elongate member 220 mounted on a pedestal 222 via torsional beams 224. A pair of actuation electrodes 226 can be mounted on substrate 102 below elongate member 220. In operation, a charge is applied to actuation electrodes 226 to move member 224 into and out of the optical path. In FIGS. 5A and 5B, the optical MEMS device is shown in the actuated position to affect the flow of light across substrate 202. In its unactuated state, the optical MEMS device illustrated in FIGS. 5A and 5B may be oriented such that elongate member 220 is substantially parallel to substrate 202.

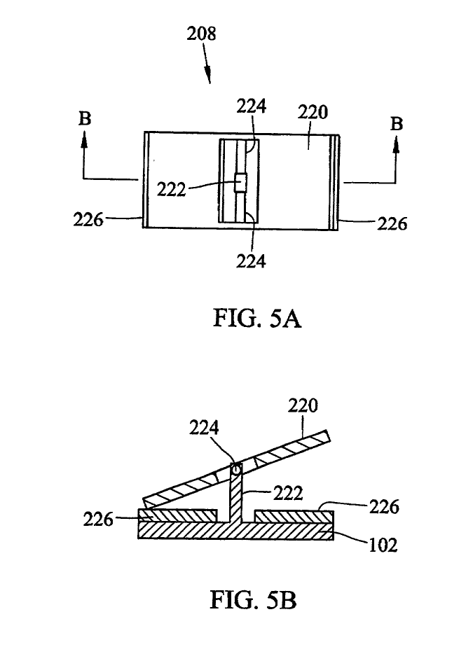

FIGS. 6A and 6B illustrate yet another optical MEMS device that can be used to affect the optical path in an across-wafer optical MEMS device with a protective lid according to an embodiment of the present invention. More particularly, FIG. 6A is a top view and FIG. 6B is an end view of a plurality of cantilever beam optical MEMS devices, each comprising a bimetallic spring. Optical MEMS devices 228 can be made of magnetic materials or piezoelectric materials. As illustrated in FIG. 6B, optical MEMS device 228 comprises a bimetallic spring having a first layer 230 made of one material and a second layer 232 made of a second material with a different spring constant than the first material. An energy source 234 may be used to apply a charge or a current to an actuation layer 236 to pull optical MEMS device towards substrate 102. If optical MEMS device comprises a magnetic material, energy source 234 can be a current source. Alternatively, if optical MEMS device 228 comprises a piezoelectric material, energy source 234 can be a voltage source. A third example, if optical MEMS device 228 use electrostatic attraction, energy source 234 can be a charge or voltage source.

In operation, in its unactuated state, optical MEMS device affects the flow of light across substrate 102. When energy source 234 applies a current or a voltage to actuation layer 236, optical MEMS device 228 moves towards actuation layer 236 and allows light to pass unimpeded across surface 108 of substrate 102.

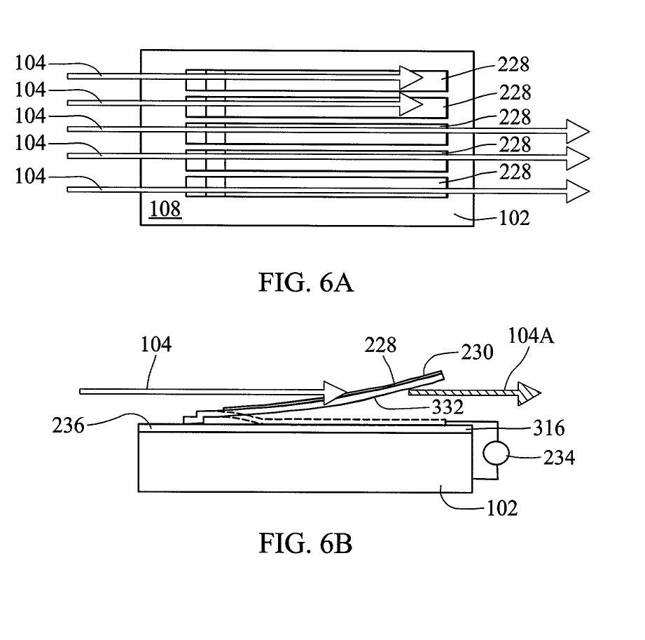

FIG. 7 illustrates yet another across-wafer optical MEMS device according to an embodiment of the present invention. In FIG. 7, the optical MEMS device comprises a plate 228 suspended from a torsional pivot 230. Plate 228 can include a first side 232 made of a magnetic material, such as permalloy and a second side 234 made of a non-magnetic material, such as silicon. An external magnetic field Hₑₓₜ can be applied to plate 228 to move plate 228 about pivot 230 and selectively affect the flow of light across substrate 230.

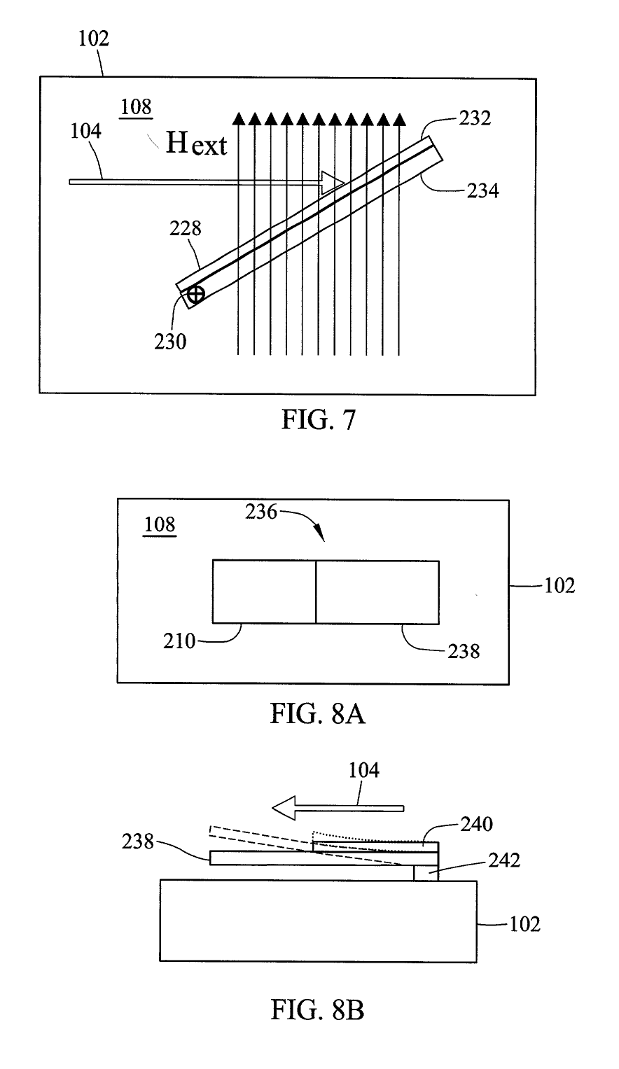

FIGS. 8A and 8B illustrate yet another optical MEMS device suitable for use with embodiments of the present invention. In FIGS. 8A and 8B the optical MEMS device 236 comprises a cantilever beam 238 having a piezoelectric material 240. More particularly, in FIG. 8B, cantilever beam 238 is mounted on substrate 102 via a pivot 242. A piezoelectric material 240 is located on one end of beam 238. When a voltage is applied to piezoelectric material 240, piezoelectric material 240 bends, thus moving beam 238 into the optical path affect the flow of light across substrate 102.

Thus, as illustrated above, a variety of optical MEMS devices can be located on substrate 102 to affect the flow of light across substrate 102. Because light flows across substrate 102 through apertures on opposing sides of a lid that encloses the optical MEMS devices, a plurality of optical MEMS devices can be located close to each other on the same substrate. Placing a protective lid on an across-wafer optical MEMS devices protects the device from particulate contamination during manufacturing and operation. A lid with first and second light-transmissive portions can be bonded to the substrate and placed over each individual MEMS device. Wafer level encapsulation can lower the cost of packaging the optical MEMS device or such encapsulation can eliminate the need for a first level package.

Alternatively, a lid with first and second light-transmissive portions may be bonded to the substrate and may provide the total package for a plurality of across-wafer optical MEMS devices. Using a single lid with across-wafer light-transmissive portions for multiple devices may reduce manufacturing costs over providing a lid for each device. However, as stated above, the present invention is not limited to encapsulating a plurality of optical MEMS devices with a single lid and may include both wafer and device-level encapsulation. Placing a protective lid over a plurality of across-wafer optical MEMS devices will reduce the optical path length through the lid, to the optical MEMS devices, and through the lid a second time. This is a benefit compared to conventional first level packages where optical information travels from a first optical device located at a first angle with respect to the optical MEMS device, through the lid, to the optical MEMS device, back through the lid, and to a second optical device located at a second angle with respect to the optical MEMS device. In addition, because a protective lid according to embodiments of the present invention allows light to flow from one edge of the substrate, through optical MEMS devices located on the substrate, and out another edge of the substrate, the need for complex waveguides is reduced.

It will be understood that various details of the invention may be changed without departing from the scope of the invention. Furthermore, the foregoing description is for the purpose of illustration only, and not for the purpose of limitation—the invention being defined by the claims.

What is claimed is:

1. An across-wafer optical microelectromechanical system comprising:
(a) a substrate having a first surface;
(b) an across-wafer optical MEMS device attached to the first surface for selectively altering the flow of light in a direction parallel to the first surface; and
(c) a protective lid for covering the optical MEMS device, the lid including first and second light-transmissive portions for providing an optical path in a direction parallel to the first surface.

2. The system of claim 1 wherein the substrate comprises a glass material.

3. The system of claim 1 wherein the substrate comprises a silicon material.

4. The system of claim 1 wherein the substrate comprises a gallium arsenide material.

5. The system of claim 1 wherein the across-wafer optical MEMS device comprises an elongate member having a curling portion for curling out of the plane of the first surface to alter the flow of light across the substrate.

6. The system of claim 1 wherein the across-wafer optical MEMS device comprises a sliding member for sliding across the first surface to alter the flow of light across the substrate.

7. The system of claim 1 wherein the across-wafer optical MEMS device comprises:
(a) a pedestal;
(b) an elongate member torsionally mounted on the pedestal; and
(c) an actuation electrode located below the elongate member for pivoting the elongate member about the pedestal selectively alter the flow of light across the substrate.

8. The system of claim 1 wherein the across-wafer optical MEMS device comprises a pop-up member for moving from a first position substantially parallel to the plane of the first surface to a second position substantially orthogonal to the plane of the first surface to selectively affect the flow of light across the substrate.

9. The system of claim 1 wherein the optical across-wafer MEMS device comprises a cantilever beam having a mirror mounted on an end of the cantilever beam for selectively affecting the flow of light across the substrate.

10. The system of claim 1 wherein the across-wafer optical MEMS device comprises an elongate member extending in a direction orthogonal to the first surface of the substrate and a pivot for rotationally mounting the elongate member on the substrate, wherein the elongate member rotates about the pivot to selectively affect the flow of light across the substrate.

11. The system of claim 1 wherein the across-wafer optical MEMS device comprises a bi-metallic spring having a resting position for affecting the flow of light across the substrate and an actuated position for allowing light to pass across the substrate.

12. The system of claim 11 wherein the bi-metallic spring includes a piezoelectric material for moving the spring from the resting position to the actuated position.

13. The system of claim 11 wherein the bi-metallic spring includes a magnetic material for moving the spring from the first position to the actuated position.

14. The system of claim 1 comprising a plurality of across-wafer optical MEMS devices located on the substrate for affecting the flow of light across the first surface.

15. The system of claim 1 wherein the protective lid is made of the same material as the substrate.

16. The system of claim 1 wherein the protective lid is made from a different material than the substrate.

17. The system of claim 1 wherein the first and second light-transmissive portions comprise apertures.

18. The system of claim 1 wherein the first and second light-transmissive portions comprise a light-transmissive material.

19. The system of claim 18 comprising an anti-reflective film located on predetermined surfaces of the light-transmissive portions.

20. An across-wafer optical mircoelectromechanical system comprising:
(a) a substrate having a first surface;
(b) an across-wafer optical MEMS device located on the first surface for selectively altering the flow of light in a direction parallel to the first surface; and
(c) a protective lid for covering the optical MEMS device, wherein at least one of the substrate and the lid include first and second light-transmissive portions for providing an optical path.

21. The system of claim 20 wherein the substrate comprises a glass material.

22. The system of claim 20 wherein the substrate comprises a silicon material.

23. The system of claim 20 wherein the substrate comprises a gallium arsenide material.

24. The system of claim 20 wherein the across-wafer optical MEMS device comprises an elongate member having a curling portion for curling out of the plane of the first surface to alter the flow of light across the substrate.

25. The system of claim 20 wherein the across-wafer optical MEMS device comprises a sliding member for sliding across the first surface to alter the flow of light across the substrate.

26. The system of claim 20 wherein the across-wafer optical MEMS device comprises:
(a) a pedestal;
(b) an elongate member torsionally mounted on the pedestal; and
(c) an actuation electrode located below the elongate member for pivoting the elongate member about the pedestal selectively alter the flow of light across the substrate.

27. The system of claim 20 wherein the across-wafer optical MEMS device comprises a pop-up member for moving from a first position substantially parallel to the plane of the first surface to a second position substantially orthogonal to the plane of the first surface to selectively affect the flow of light across the substrate.

28. The system of claim 20 wherein the across-wafer optical MEMS device comprises a cantilever beam having a mirror mounted on an end of the cantilever beam for selectively affecting the flow of light across the substrate.

29. The system of claim 20 wherein the across-wafer optical MEMS device comprises an elongate member extending in a direction orthogonal to the first surface of the substrate and a pivot for rotationally mounting the elongate member on the substrate, wherein the elongate member rotates about the pivot to selectively affect the flow of light across the substrate.

30. The system of claim 20 wherein the across-wafer optical MEMS device comprises a bi-metallic spring having a resting position for affecting the flow of light across the substrate and an actuated position for allowing light to pass across the substrate.

31. The system of claim 30 wherein the bi-metallic spring includes a piezoelectric material for moving the spring from the resting position to the actuated position.

32. The system of claim 30 wherein the bi-metallic spring includes a magnetic material for moving the spring from the first position to the actuated position.

33. The system of claim 20 comprising a plurality of across-wafer optical MEMS devices located on the substrate for affecting the flow of light across the first surface.

34. The system of claim 20 wherein the protective lid is made of the same material as the substrate.

35. The system of claim 20 wherein the protective lid is made from a different material than the substrate.

36. The system of claim 20 wherein the first and second light-transmissive portions comprise apertures.

37. The system of claim 20 wherein the first and second light-transmissive portions comprise a light-transmissive material.

38. The system of claim 20 comprising an anti-reflective film located on predetermined surfaces of the light-transmissive portions.

39. A method for passing light through an optical MEMS device package in across-wafer direction, the method comprising:
(a) passing light through a first light-transmissive portion of an optical MEMS device package;
(b) guiding the light in a direction substantially parallel to a surface of a substrate to which an optical MEMS device is attached;
(c) selectively altering the flow of light across the first surface using the optical MEMS device; and
(d) passing the light from the optical MEMS device package through a second light-transmissive portion.

40. The method of claim 39 wherein passing the light through a first light-transmissive portion includes passing the light through an aperture.

41. The method of claim 39 wherein passing the light through a first light-transmissive portion includes passing the light through a light-transmissive material.

42. The method of claim 39 wherein guiding the light in a direction substantially parallel to a surface of a substrate includes guiding the light through a cavity formed by the optical MEMS device package.

43. The method of claim 39 wherein selectively altering the flow of light across the first surface includes reflecting the light as it passes across the first surface.

44. The method of claim 39 wherein selectively altering the flow of light as it passes across the first surface includes changing the wavelength content of the light as it passes across the first surface.

45. The method of claim 39 wherein selectively altering the flow of light as it passes across the first surface includes selectively blocking the light as it passes across the first surface.

46. The method of claim 39 wherein passing the light from the optical MEMS device through a second light-transmissive portion includes passing the light through an aperture.

47. The method of claim 39 wherein passing the light from the optical MEMS device through a second light-transmissive portion includes passing the light through a light-transmissive material.
